(19) United States
(12) Patent Application Publication
(10) Pub. No.: US 2021/0288628 A1
(43) Pub. Date: Sep. 16, 2021

(54) ACOUSTIC WAVE DEVICE, FILTER, AND MULTIPLEXER

(71) Applicant: TAIYO YUDEN CO., LTD., Tokyo (JP)

(72) Inventors: Takuya NISHIMURA, Tokyo (JP); Toshiharu NAKAZATO, Tokyo (JP); Toshio NISHIZAWA, Tokyo (JP); Naoki TAKAHASHI, Tokyo (JP)

(73) Assignee: TAIYO YUDEN CO., LTD., Tokyo (JP)

(21) Appl. No.: 17/184,910

(22) Filed: Feb. 25, 2021

(30) Foreign Application Priority Data
Mar. 13, 2020 (JP) 2020-044458

(51) Int. Cl. H03H 9/02; H03H 9/145; H03H 9/64

(52) U.S. Cl. CPC H03H 9/02574; H03H 9/6406; H03H 9/02834; H03H 9/145

(57) ABSTRACT

An acoustic wave device includes a support substrate, a piezoelectric layer located over the support substrate, a pair of comb-shaped electrodes disposed on the piezoelectric layer and including electrode fingers exciting an acoustic wave, a temperature compensation film interposed between the support substrate and the piezoelectric layer, having a thickness equal to or less than 2 times an average pitch of the electrode fingers, and having a temperature coefficient of elastic constant opposite in sign to that of the piezoelectric layer, and a boundary layer interposed between the support substrate and the temperature compensation film and having a thickness equal to or greater than 2.2 times the average pitch, an acoustic velocity of a lateral wave propagating through the boundary layer being less than that of a lateral wave propagating through the support substrate and greater than that of a lateral wave propagating through the temperature compensation film.

### CROSS-REFERENCE TO RELATED APPLICATION

This application is based upon and claims the benefit of priority of the prior Japanese Patent Application No. 2020-044458, filed on Mar. 13, 2020, the entire contents of which are incorporated herein by reference.

### FIELD

A certain aspect of the present embodiments relates to an acoustic wave device, a filter, and a multiplexer.

### BACKGROUND

Surface acoustic wave resonators have been known as acoustic wave resonators used in communication devices such as smartphones. It is known to attach a piezoelectric layer forming the surface acoustic wave resonator to a support substrate. It is known to adjust the thickness of the piezoelectric layer to be equal to or less than the wavelength of the surface acoustic wave as disclosed in, for example, Japanese Patent Application Publication No. 2017-034363 (Patent Document 1). It is known to provide a low acoustic velocity film, which has a lower acoustic velocity than the piezoelectric layer, between the piezoelectric layer and the support substrate as disclosed in, for example, Japanese Patent Application Publication No. 2015-115870 (Patent Document 2), International Publication No. WO2013/191122 (Patent Document 3), U.S. patent Ser. No. 10/020,796 (Patent Document 4), and International Publication No. WO2017/043427 (Patent Document 5). It is known to reduce spurious emissions by providing a high acoustic velocity film (a boundary layer), which has a higher acoustic velocity than the piezoelectric layer, between the low acoustic velocity film and the support substrate and adjusting the thickness of the high acoustic velocity film to be within a predetermined range as disclosed in, for example, Patent Documents 2 and 3.

### SUMMARY

In Patent Documents 2 and 3, a simulation is conducted under the condition where the support substrate is made of glass, and the boundary layer (the high acoustic velocity film) is made of aluminum oxide. This condition is considered to correspond to a case where the acoustic velocity of the support substrate is less than the acoustic velocity of the boundary layer. However, there is a case where the acoustic velocity of the support substrate is adjusted to be greater than the acoustic velocity of the boundary layer. The principles for reducing spurious emissions in such a case have not been known.

The objective of the present disclosure is to reduce spurious emissions when the acoustic velocity of the lateral wave propagating through the support substrate is greater than the acoustic velocity of the lateral wave propagating through the boundary layer.

According to a first aspect of the present disclosure, there is provided an acoustic wave device including: a support substrate; a piezoelectric layer located over the support substrate; at least one pair of comb-shaped electrodes disposed on the piezoelectric layer, each of the at least one pair of comb-shaped electrodes including electrode fingers that excite an acoustic wave; a temperature compensation film interposed between the support substrate and the piezoelectric layer, the temperature compensation film having a thickness equal to or less than 2 times an average pitch of the electrode fingers, a temperature coefficient of elastic constant of the temperature compensation film being opposite in sign to a temperature coefficient of elastic constant of the piezoelectric layer; and a boundary layer interposed between the support substrate and the temperature compensation film, the boundary layer having a thickness equal to or greater than 2.2 times the average pitch of the electrode fingers, an acoustic velocity of a lateral wave propagating through the boundary layer being less than an acoustic velocity of a lateral wave propagating through the support substrate and greater than an acoustic velocity of a lateral wave propagating through the temperature compensation film.

According to a second aspect of the present embodiments, there is provided a filter including the above acoustic wave device.

According to a third aspect of the present embodiments, there is provided a multiplexer including the above filter.

### BRIEF DESCRIPTION OF THE DRAWINGS

FIG. 1A is a plan view of an acoustic wave resonator in a first embodiment, and

FIG. 1B is a cross-sectional view of the acoustic wave resonator in the first embodiment;

FIG. 2A to FIG. 2F illustrate the frequency characteristics of admittance |Y| in a simulation;

FIG. 3A to FIG. 3C illustrate the frequency characteristics of admittance |Y| in the simulation;

FIG. 4A to FIG. 4I are Smith charts of impedance in the simulation;

FIG. 5A to FIG. 5D are graphs of response versus the thickness T1 of a boundary layer in the simulation;

FIG. 6A and FIG. 6B are cross-sectional views of acoustic wave resonators in accordance with first and second variations of the first embodiment, respectively;

FIG. 7A and FIG. 7B are cross-sectional views of acoustic wave resonators in accordance with third and fourth variations of the first embodiment, respectively;

FIG. 8A to FIG. 8C are cross-sectional views of acoustic wave resonators in accordance with fourth to sixth variations of the first embodiment, respectively; and

FIG. 9A is a circuit diagram of a filter in accordance with a second embodiment, and FIG. 9B is a circuit diagram of a duplexer in accordance with a first variation of the second embodiment.

### DETAILED DESCRIPTION

Hereinafter, a description will be given of embodiments of the present disclosure with reference to the accompanying drawings.

### First Embodiment

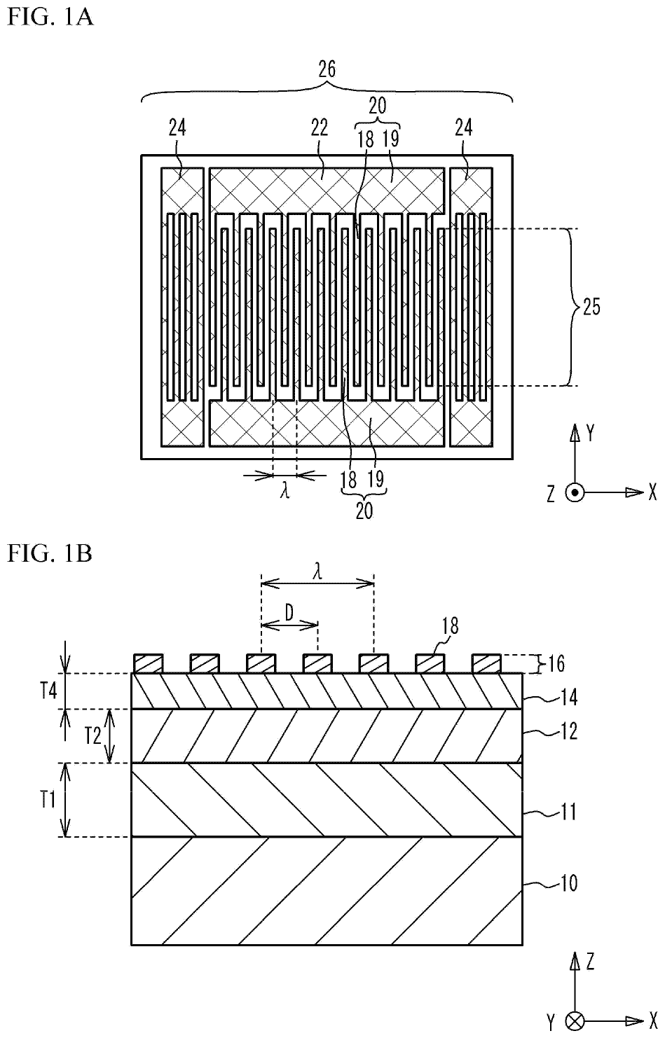

A first embodiment describes an example where an acoustic wave device includes an acoustic wave resonator. FIG. 1A is a plan view of an acoustic wave resonator in the first embodiment, and FIG. 1B is a cross-sectional view of the acoustic wave resonator in the first embodiment. The direction in which electrode fingers are arranged is defined as an X direction, the direction in which the electrode fingers extend (the extension direction of the electrode fingers) is defined as a Y direction, and the direction in which a support substrate and a piezoelectric layer are stacked (the stack direction of the support substrate and the piezoelectric layer) is defined as a Z direction. The X direction, the Y direction, and the Z direction do not necessarily correspond to the X-axis orientation or the Y-axis orientation of the crystal orientation of the piezoelectric layer. When the piezoelectric layer is a rotated Y-cut X-propagation substrate, the X direction is the X-axis orientation of the crystal orientation.

As illustrated in FIG. 1A and FIG. 1B, a piezoelectric layer 14 is located over a support substrate 10. A temperature compensation film 12 is interposed between the support substrate 10 and the piezoelectric layer 14. A boundary layer 11 is interposed between the temperature compensation film 12 and the support substrate 10. The thickness of the boundary layer 11 is represented by T1, the thickness of the temperature compensation film 12 is represented by T2, and the thickness of the piezoelectric layer 14 is represented by T4. The thickness means the respective lengths of the substrate, the layer, and the film in the Z direction that is the direction in which the support substrate 10 and the piezoelectric layer 14 are stacked.

An acoustic wave resonator 26 is disposed on the piezoelectric layer 14. The acoustic wave resonator 26 includes an IDT 22 and reflectors 24. The reflectors 24 are located at both sides of the IDT 22 in the X direction. The IDT 22 and the reflectors 24 are formed of a metal film 16 on the piezoelectric layer 14.

The IDT 22 includes a pair of comb-shaped electrodes 20 opposite to each other. The comb-shaped electrode 20 includes a plurality of electrode fingers 18 and a bus bar 19 to which the electrode fingers 18 are coupled. The region where the electrode fingers 18 of one of the pair of the comb-shaped electrodes 20 overlap with the electrode fingers 18 of the other of the pair of the comb-shaped electrodes 20 is an overlap region 25. The length of the overlap region 25 is an aperture length. In at least a part of the overlap region 25, the electrode fingers 18 of one of the pair of the comb-shaped electrodes 20 and the electrode fingers 18 of the other of the pair of the comb-shaped electrodes 20 are alternately arranged. In the overlap region 25, the acoustic wave that the electrode fingers 18 mainly excite propagates mainly in the X direction. The pitch of the electrode fingers 18 of one of the pair of the comb-shaped electrodes 20 is approximately equal to the wavelength λ of the acoustic wave. When the pitch of the electrode fingers 18 (the pitch between the centers of the electrode fingers 18) is represented by D, the pitch of the electrode fingers 18 of one of the pair of the comb-shaped electrodes 20 is equal to two times the pitch D. The reflectors 24 reflect the acoustic wave (the surface acoustic wave) excited by the electrode fingers 18 of the IDT 22. Thus, the acoustic wave is confined within the overlap region 25 of the IDT 22.

The piezoelectric layer 14 is, for example, a monocrystalline lithium tantalate (LiTaO₃) layer or a monocrystalline lithium niobate (LiNbO₃) layer, and is, for example, a rotated Y-cut X-propagation lithium tantalate layer or a rotated Y-cut X-propagation lithium niobate layer.

The support substrate 10 is, for example, a sapphire substrate, a silicon substrate, or a silicon carbide substrate. The sapphire substrate is a monocrystalline Al₂O₃ substrate, the silicon substrate is a monocrystalline or polycrystalline silicon substrate, and the silicon carbide substrate is a polycrystalline or monocrystalline SiC substrate. The linear expansion coefficient in the X direction of the support substrate 10 is less than the linear expansion coefficient in the X direction of the piezoelectric layer 14. Therefore, the frequency temperature dependence of the acoustic wave resonator can be reduced.

The temperature compensation film 12 has a temperature coefficient of elastic constant opposite in sign to the temperature coefficient of elastic constant of the piezoelectric layer 14. For example, the temperature coefficient of elastic constant of the piezoelectric layer 14 has a negative value, while the temperature coefficient of elastic constant of the temperature compensation film 12 has a positive value. The temperature compensation film 12 is, for example, an additive-free silicon oxide (SiO₂) film or a silicon oxide (SiO₂) film containing additive elements such as fluorine, and is, for example, an amorphous layer. Therefore, the temperature coefficient of frequency of the acoustic wave resonator can be reduced. When the temperature compensation film 12 is a silicon oxide film, the acoustic velocity of the lateral wave propagating through the temperature compensation film 12 is less than the acoustic velocity of the lateral wave propagating through the piezoelectric layer 14. The lateral wave is, for example, a bulk wave.

The acoustic velocity of the lateral wave propagating through the boundary layer 11 is greater than the acoustic velocity of the lateral wave propagating through the temperature compensation film 12. Therefore, the lateral wave is confined within the piezoelectric layer 14 and the temperature compensation film 12. Furthermore, the acoustic velocity of the lateral wave propagating through the boundary layer 11 is less than the acoustic velocity of the lateral wave propagating through the support substrate 10. The boundary layer 11 is, for example, polycrystalline or amorphous, and is an aluminum oxide film, a silicon nitride film, or an aluminum nitride film.

The metal film 16 is a film mainly composed of, for example, aluminum (Al), copper (Cu), or molybdenum (Mo). Here, “mainly composed of a certain material” means that impurities are contained intentionally or unintentionally, and 50 atomic % or greater of the certain material, or 80 atomic % or greater of the certain material is contained, for example. An adhesion film such as a titanium (Ti) film or a chrome (Cr) film may be interposed between the electrode finger 18 and the piezoelectric layer 14. The adhesion film is thinner than the electrode finger 18. An insulating film may be provided so as to cover the electrode finger 18. The insulating film serves as a protective film or a temperature compensation film.

The wavelength λ of the acoustic wave is, for example, 1 μm to 6 μm. When two electrode fingers 18 are defined as a pair, the number of pairs is, for example, 20 pairs to 300 pairs. The duty ratio of the IDT 22 is the value calculated by dividing the width of the electrode finger 18 by the pitch of the electrode fingers 18, and is, for example, 30% to 70%. The aperture length of the IDT 22 is, for example, 10λ to 50λ.

Table 1 lists Young's modulus, Poisson ratio, the density, and the acoustic velocity of the lateral wave for each material. The acoustic velocity V of the lateral wave is calculated with the following equation (1) using Young's modulus E, Poisson ratio γ, and the density ρ.

$$V = \frac{E}{2 ρ ( 1 + γ )} \qquad ( 1 )$$

TABLE 1

| | LT | Al₂O₃ | SiO₂ | SA | LN | Si | AlN | SiN | SiC |
|---|---|---|---|---|---|---|---|---|---|
| Young's | 254 | 164 | 77 | 470 | 177 | 170 | 290 | 250 | 748 |
| modulus | | | | | | | | | |
| [Gpa] | | | | | | | | | |
| Poisson | 0.21 | 0.24 | 0.25 | 0.25 | 0.21 | 0.28 | 0.24 | 0.23 | 0.45 |
| ratio | | | | | | | | | |
| Density | 7450 | 3150 | 2270 | 3970 | 4640 | 2329 | 3260 | 3100 | 3216 |
| [kg/m³] | | | | | | | | | |
| Acoustic | 3754 | 4582 | 3684 | 6882 | 3970 | 5340 | 5989 | 5726 | 8956 |
| velocity | | | | | | | | | |
| of lateral | | | | | | | | | |
| wave [m/s] | | | | | | | | | |

In Table 1, LT is monocrystalline lithium tantalate, Al₂O₃ is polycrystalline aluminum oxide, SiO₂ is amorphous silicon oxide, and SA is sapphire (monocrystalline aluminum oxide). LN is monocrystalline lithium niobate, Si is polycrystalline silicon, AlN is polycrystalline aluminum nitride, SiN is polycrystalline silicon nitride, and SiC is polycrystalline silicon carbide.

As presented in Table 1, when a lithium tantalate substrate or a lithium niobate substrate is used as the piezoelectric layer 14, use of a silicon oxide film as the temperature compensation film 12 causes the acoustic velocity of the lateral wave propagating through the temperature compensation film 12 to be less than the acoustic velocity of the lateral wave propagating through the piezoelectric layer 14. Use of an aluminum oxide film, an aluminum nitride film, or a silicon nitride film as the boundary layer 11 causes the acoustic velocity of the lateral wave propagating through the boundary layer 11 to be greater than the acoustic velocity of the lateral wave propagating through the temperature compensation film 12. Use of a sapphire substrate or a silicon carbide substrate as the support substrate 10 causes the acoustic velocity of the lateral wave propagating through the support substrate 10 to be greater than the acoustic velocity of the lateral wave propagating through the boundary layer 11. When the boundary layer 11 is an aluminum oxide film, the acoustic velocity of the lateral wave propagating through the support substrate 10 is greater than the acoustic velocity of the lateral wave propagating through the boundary layer 11 even when the support substrate 10 is a silicon substrate.

Hereinafter, the function of each layer and a preferable range of the thickness of each layer will be examined. The temperature compensation film 12 has a function that reduces the temperature coefficient of frequency of the acoustic wave resonator. To have this function, the energy of the acoustic wave of the main response is required to be present to some extent within the temperature compensation film 12. The section in which the energy of the surface acoustic wave is concentrated depends on the type of the surface acoustic wave. However, typically, the energy of the surface acoustic wave is concentrated in the section from the upper surface of the piezoelectric layer 14 to the depth of 2λ (λ is the wavelength of the acoustic wave), particularly in the section from the upper surface of the piezoelectric layer 14 to the depth of λ. Therefore, the thickness T4 of the piezoelectric layer 14 is preferably 2λ or less, more preferably λ or less, further preferably 0.6λ or less.

The boundary layer 11 or the support substrate 10 of which the acoustic velocity of the lateral wave is greater than that of the temperature compensation film 12 is provided under the temperature compensation film 12. This structure allows the energy of the main response of the acoustic wave to be confined within the piezoelectric layer 14 and the temperature compensation film 12. Thus, the characteristics of the main response improve. However, an unnecessary wave such as a bulk wave is reflected by the boundary face between the temperature compensation film 12 and the boundary layer 11 or the boundary face between the temperature compensation film 12 and the support substrate 10. This increases the spurious response. When the thickness T2 of the temperature compensation film 12 is adjusted to be k or less, preferably 0.6λ or less, at least a part of the unnecessary wave passes through the temperature compensation film 12 and reaches the boundary layer 11. In addition, the acoustic wave of the main response is confined within the temperature compensation film 12 and the piezoelectric layer 14. Thus, the loss is reduced.

In Patent Documents 2 and 3, the acoustic velocity of the lateral wave propagating through the support substrate 10 is less than the acoustic velocity of the lateral wave propagating through the boundary layer 11 (a high acoustic velocity film). Thus, the unnecessary wave propagating from the temperature compensation film 12 (a low acoustic velocity film) into the boundary layer 11 propagates through the boundary layer 11 to the support substrate 10. Patent Documents 2 and 3 describe that as the boundary layer 11 is thinned, the spurious response due to the unnecessary response is reduced.

However, the acoustic velocity of the lateral wave propagating through the support substrate 10 may become greater than the acoustic velocity of the lateral wave propagating through the boundary layer 11. For example, when a hard material and/or a material having a high thermal conductivity is selected as the support substrate 10, the acoustic velocity of the lateral wave propagating through the support substrate 10 becomes greater than the acoustic velocity of the lateral wave propagating through the boundary layer 11. In this case, the unnecessary wave is reflected by the boundary face between the support substrate 10 and the boundary layer 11. Thus, it is considered that the preferable range of the thickness T1 of the boundary layer 11 is different from those in Patent Documents 2 and 3.

### Simulation

Thus, a simulation was conducted. Simulation conditions are as follows.

Support substrate 10: Sapphire substrate

Boundary layer 11: Aluminum oxide film

Temperature compensation film 12: Silicon oxide film, T2=0.1λ

Piezoelectric layer 14: 42° rotated Y-cut X-propagation lithium tantalate substrate, T4=0.3λ

Metal film 16: Aluminum film with a thickness of 0.1λ

Wavelength of the acoustic wave: 1.5 μm

The acoustic velocity of the lateral wave propagating through each layer is as follows.

Support substrate 10: 6881.5 m/s

Boundary layer 11: 4581.8 m/s

Temperature compensation film 12: 3683.5 m/s

Piezoelectric layer 14: 3753.5 m/s

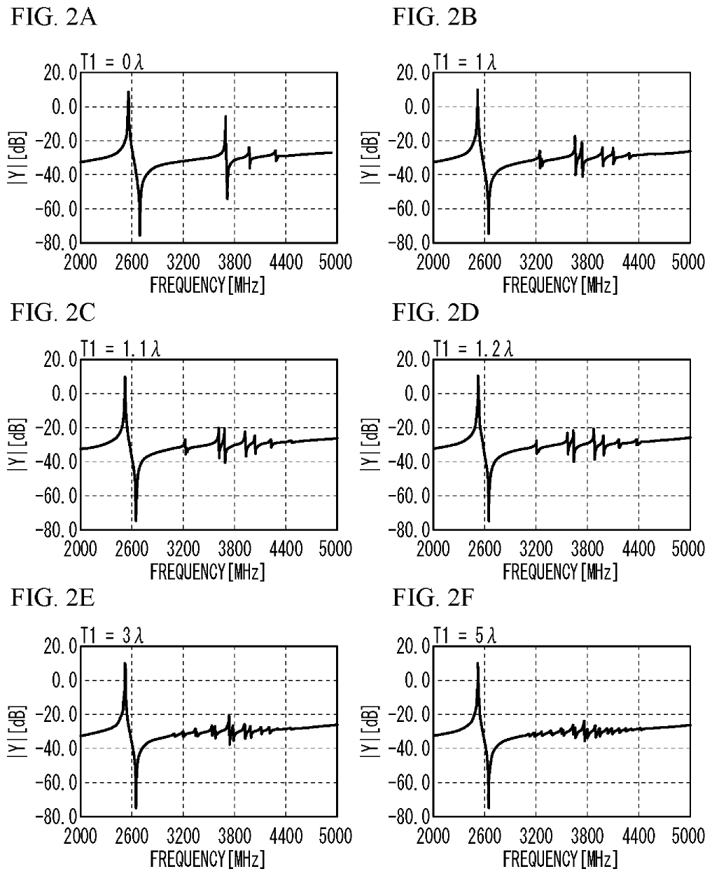

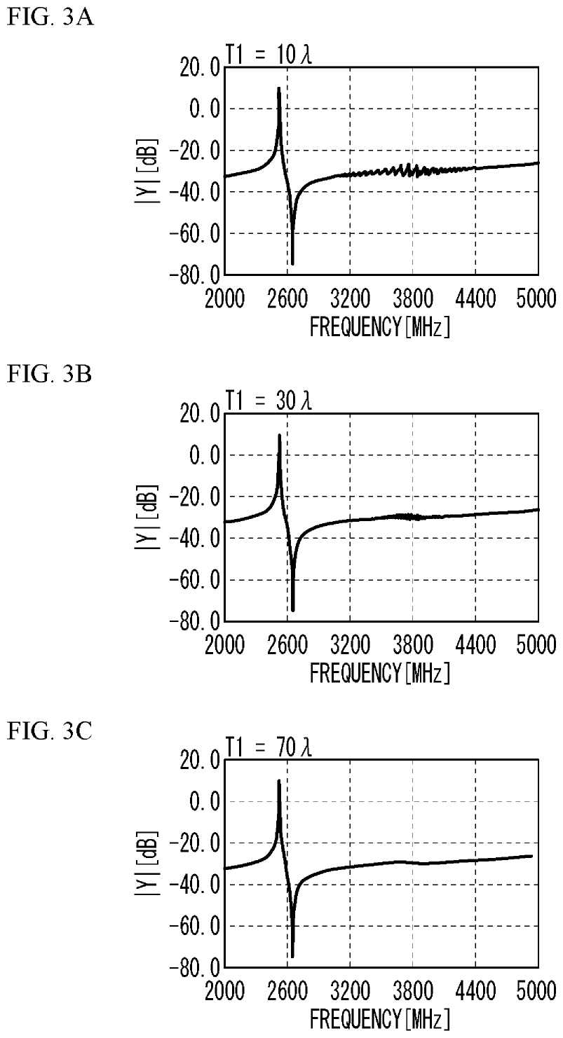

FIG. 2A to FIG. 3C illustrate frequency characteristics of admittance |Y| in the simulation. FIG. 2A to FIG. 3C are graphs of the magnitude of the admittance of the acoustic wave resonator versus frequency under the conditions that the thickness T1 of the boundary layer 11 was configured to be 0λ, 1λ, 1.1λ, 1.2λ, 3λ, 5λ, 10λ, 30λ, and 70λ, respectively.

In FIG. 2A to FIG. 3C, the response at around 2600 MHz is a main response, and the response in a range from 3200 MHz to 4400 MHz is a high-frequency spurious response. As illustrated in FIG. 2A to FIG. 3C, even when the thickness T1 of the boundary layer 11 increases, the main response does not deteriorate. By contrast, the spurious response decreases as the thickness T1 increases.

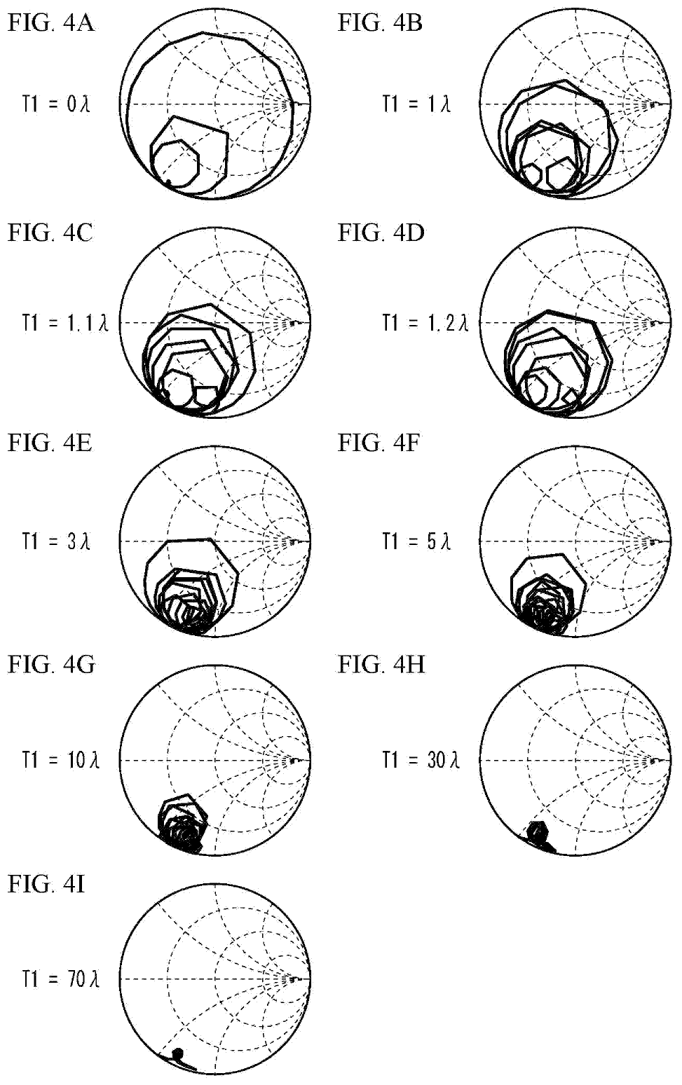

FIG. 4A to FIG. 4I are Smith charts of impedance in the simulation. Smith chart indicates the impedance of the acoustic wave resonator in the frequency range of 3100 MHz to 4600 MHz. As illustrated in FIG. 4A to FIG. 4I, as the thickness T1 of the boundary layer 11 increases, the disparity of the impedance due to the high-frequency spurious emission decreases.

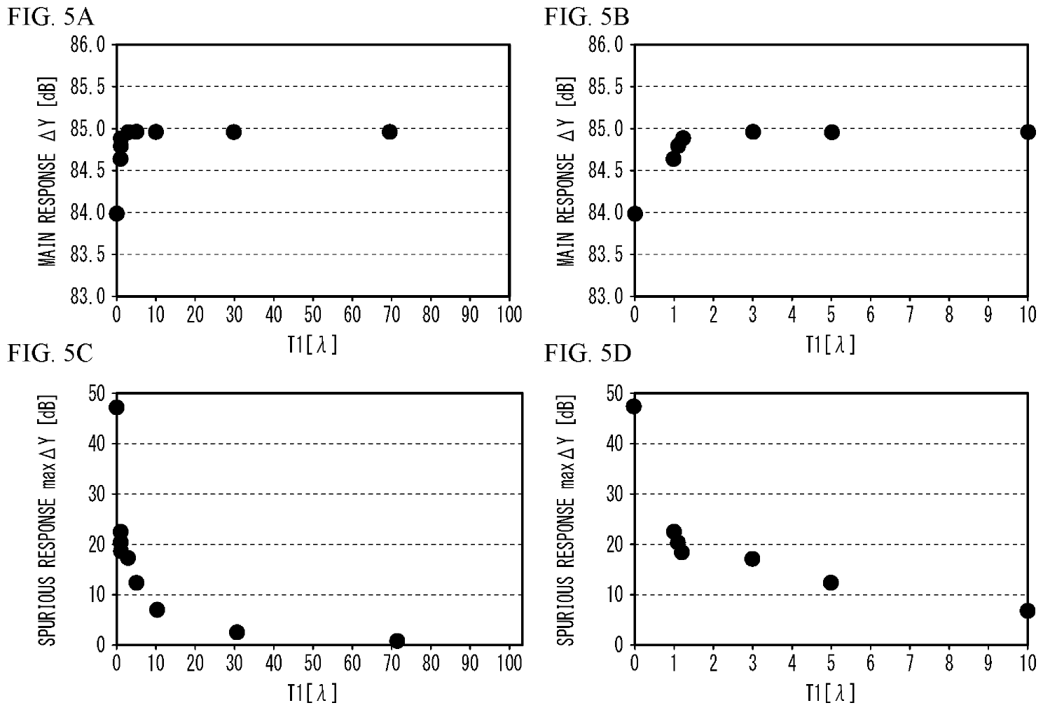

FIG. 5A to FIG. 5D are graphs of the response versus the thickness T1 of the boundary layer in the simulation. FIG. 5A illustrates the main response, and FIG. 5B enlarges FIG. 5A in the range of the thickness T1 of 10λ or less. FIG. 5C illustrates the spurious response, and FIG. 5D enlarges FIG. 5C in the range of the thickness T1 of 10λ or less. The main response ΔY is the difference between the admittance |Y| at the resonant frequency and the admittance |Y| at the antiresonant frequency around 2600 MHz in FIG. 2A to FIG. 3C. The spurious response max ΔY is the largest ΔY among the responses ΔY in the range from 3200 MHz to 4600 MHz in FIG. 2A to FIG. 3C.

As illustrated in FIG. 5A and FIG. 5B, even when the thickness T1 of the boundary layer 11 is varied from 0λ to 70λ, the main response ΔY varies from 84 dB to 85.5 dB, and little varies. In more detail, when the thickness T1 becomes 1.1λ or less, the main response ΔY decreases a little, and when the thickness T1 becomes 1λ or less, the main response ΔY further decreases.

As illustrated in FIG. 5C and FIG. 5D, as the thickness T1 of the boundary layer 11 increases, the spurious response maxΔY decreases. As illustrated in FIG. 5C, when the thickness T1 becomes 10λ or less, the spurious response maxΔY increases. As illustrated in FIG. 5D, when the thickness T1 becomes 1.1λ or less, the spurious response maxΔY rapidly increases, and becomes 20 dB or greater.

The simulation described above reveals that it is effective to increase the thickness of the boundary layer 11 to reduce the spurious response. This is considered because the unnecessary wave reflected by the boundary face between the boundary layer 11 and the support substrate 10 is inhibited from returning to the piezoelectric layer 14 by increasing the thickness of the boundary layer 11. This result is opposite to the result of the simulation in Patent Documents 2 and 3. As described above, it is revealed that when the acoustic velocity of the lateral wave propagating through the support substrate 10 is greater than the acoustic velocity of the lateral wave propagating through the boundary layer 11, the behavior of the spurious response with respect to the thickness T1 of the boundary layer 11 is opposite to those in Patent Documents 2 and 3.

In the first embodiment, the thickness T2 of the temperature compensation film 12 having a temperature coefficient of elastic constant opposite in sign to the temperature coefficient of elastic constant of the piezoelectric layer 14 is adjusted to be equal to or less than two times the average pitch of the electrode fingers 18 (i.e., equal to or less than one time the wavelength k of the acoustic wave). This configuration causes the unnecessary wave to pass through the boundary face between the temperature compensation film 12 and the boundary layer 11, and the unnecessary wave therefore propagates into the boundary layer 11. In addition, since the acoustic wave of the main response is confined within the piezoelectric layer 14 and the temperature compensation film 12, the main response is increased. The thickness T1 of the boundary layer 11 of which the acoustic velocity of the lateral wave is less than the acoustic velocity of the lateral wave propagating through the support substrate 10 and greater than the acoustic velocity of the lateral wave propagating through the temperature compensation film 12 is adjusted to be equal to or greater than 2.2 times the average pitch of the electrode fingers 18 (equal to or greater than 1.1 times the wavelength λ of the acoustic wave). This configuration inhibits the acoustic wave reflected by the boundary face between the boundary layer 11 and the support substrate 10 from propagating into the piezoelectric layer 14, and thereby reduces the spurious response.

To cause the unnecessary wave to pass to the boundary layer 11, the thickness T2 of the temperature compensation film 12 is preferably equal to or less than 1.5 times the average pitch of the electrode fingers 18, more preferably equal to or less than 1 time the average pitch of the electrode fingers 18. To fulfill the temperature compensation function of the temperature compensation film 12, the thickness T2 is preferably equal to or greater than 0.1 times the average pitch of the electrode fingers 18, more preferably equal to or greater than 0.2 times the average pitch of the electrode fingers 18.

To reduce the spurious response, the thickness T1 of the boundary layer 11 is preferably equal to or greater than 2.5 times the average pitch of the electrode fingers 18, more preferably equal to or greater than 3.0 times the average pitch of the electrode fingers 18, further preferably equal to or greater than 4.0 times the average pitch of the electrode fingers 18. As the boundary layer 11 becomes thicker, the time it takes to form the boundary layer 11 becomes longer. Thus, the thickness T1 of the boundary layer 11 is preferably equal to or less than 100 times the average pitch of the electrode fingers 18, more preferably equal to or less than 20 times the average pitch of the electrode fingers 18.

To cause the energy of the acoustic wave of the main response to be present in the temperature compensation film 12, the thickness T4 of the piezoelectric layer 14 is preferably equal to or less than two times the average pitch of the electrode fingers 18, more preferably equal to or less than one time the average pitch of the electrode fingers 18. To cause the piezoelectric layer 14 to function, the thickness T4 of the piezoelectric layer 14 is preferably equal to or greater than 0.1 times the average pitch of the electrode fingers 18, more preferably equal to or greater than 0.2 times the average pitch of the electrode fingers 18.

When most of the energy of the surface acoustic wave exists in the section from the surface of the piezoelectric layer 14 to the depth of λ, to confine the acoustic wave of the main response within the piezoelectric layer 14 and the temperature compensation film 12 and reduce the spurious response, the distance (T2+T4) between the surface (a first surface), which is physically closer to the support substrate 10, of the temperature compensation film 12 and the surface (a second surface), which is physically closer to the comb-shaped electrodes 20, of the piezoelectric layer 14 is preferably equal to or less than 2 times the average pitch of the electrode fingers 18, more preferably equal to or less than 1.6 times the average pitch of the electrode fingers 18.

The average pitch of the electrode fingers 18 can be calculated by dividing the length in the X direction of the IDT 22 of the acoustic wave resonator 26 by the number of the electrode fingers 18.

The acoustic velocity of the lateral wave propagating through the temperature compensation film 12 may be greater than the acoustic velocity of the lateral wave propagating through the piezoelectric layer 14. However, the acoustic velocity of the lateral wave propagating through the temperature compensation film 12 is preferably less than the acoustic velocity of the lateral wave propagating through the piezoelectric layer 14 because this configuration causes the acoustic wave to be more likely to exist in the temperature compensation film 12. This configuration allows the temperature compensation film 12 to function more as a temperature compensation film. The acoustic velocity of the lateral wave propagating through the temperature compensation film 12 is preferably equal to or less than 0.99 times the acoustic velocity of the lateral wave propagating through the piezoelectric layer 14. When the acoustic velocity of the lateral wave propagating through the temperature compensation film 12 is too small, the acoustic wave is less likely to exist in the piezoelectric layer 14. Therefore, the acoustic velocity of the lateral wave propagating through the temperature compensation film 12 is preferably equal to or greater than 0.9 times the acoustic velocity of the lateral wave propagating through the piezoelectric layer 14.

The acoustic velocity of the lateral wave propagating through the boundary layer 11 is preferably equal to or greater than 1.1 times the acoustic velocity of the lateral wave propagating through the temperature compensation film 12, more preferably equal to or greater than 1.2 times the acoustic velocity of the lateral wave the temperature compensation film 12. Additionally, the acoustic velocity of the lateral wave propagating through the boundary layer 11 is preferably greater than the acoustic velocity of the lateral wave propagating through the piezoelectric layer 14. When the acoustic velocity of the lateral wave propagating through the boundary layer 11 is too large, the unnecessary wave is reflected by the boundary face between the boundary layer 11 and the temperature compensation film 12. Thus, the acoustic velocity of the lateral wave propagating through the boundary layer 11 is preferably equal to or less than 2.0 times the acoustic velocity of the lateral wave propagating through the temperature compensation film 12, more preferably equal to or less than 1.5 times the acoustic velocity of the lateral wave propagating through the temperature compensation film 12.

The acoustic velocity of the lateral wave propagating through the support substrate 10 is preferably equal to or greater than 1.1 times the acoustic velocity of the lateral wave propagating through the boundary layer 11, more preferably equal to or greater than 1.2 times the acoustic velocity of the lateral wave propagating through the boundary layer 11. The acoustic velocity of the lateral wave propagating through the support substrate 10 is preferably equal to or less than 2.0 times the acoustic velocity of the lateral wave propagating through the boundary layer 11.

The piezoelectric layer 14 is a single crystal mainly composed of lithium tantalate or lithium niobate, the temperature compensation film 12 is a polycrystal mainly composed of silicon oxide or an amorphia mainly composed of silicon oxide, the boundary layer 11 is a polycrystal mainly composed of aluminum oxide or an amorphia mainly composed of aluminum oxide, and the support substrate 10 is a sapphire substrate or a silicon carbide substrate. This configuration reduces the spurious response as described in the simulation. The term “mainly composed of a certain material” means that impurities are contained intentionally or unintentionally, and for example, 50 atomic % or greater of the certain material, or 80 atomic % or greater of the certain material is contained.

### First Variation of the First Embodiment

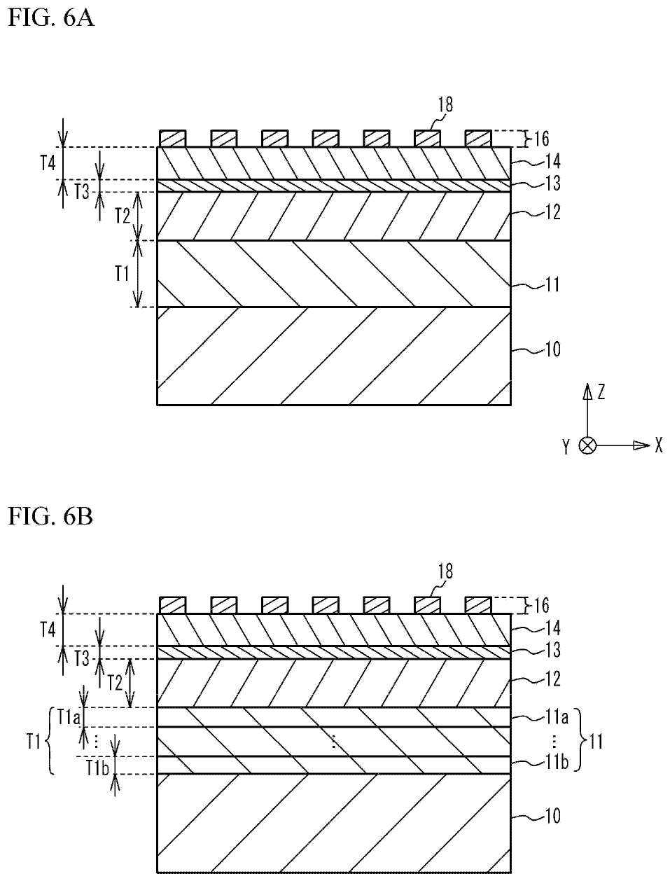

FIG. 6A is a cross-sectional view of an acoustic wave resonator in accordance with a first variation of the first embodiment. As illustrated in FIG. 6A, a bonding layer 13 is interposed between the piezoelectric layer 14 and the temperature compensation film 12. The bonding layer 13 bonds the piezoelectric layer 14 with the temperature compensation film 12. When it is difficult to bond the piezoelectric layer 14 directly with the temperature compensation film 12, the bonding layer 13 may be provided. The bonding layer 13 is, for example, an aluminum oxide film, a silicon film, an aluminum nitride film, a silicon nitride film, or a silicon carbide film. The thickness T3 of the bonding layer 13 is preferably 20 nm or less, more preferably 10 nm or less so as not to impair the functions of the piezoelectric layer 14 and the temperature compensation film 12. Not to impair the function as the bonding layer 13, the thickness T3 is preferably 1 nm or greater, more preferably 2 nm or greater. To confine the acoustic wave of the main response within the piezoelectric layer 14, the acoustic velocity of the lateral wave propagating through the bonding layer 13 is preferably greater than the acoustic velocity of the lateral wave propagating through the temperature compensation film 12. Other structures are the same as those of the first embodiment, and the description thereof is thus omitted.

### Second Variation of the First Embodiment

FIG. 6B is a cross-sectional view of an acoustic wave resonator in accordance with a second variation of the first embodiment. As illustrated in FIG. 6B, the boundary layer 11 includes a plurality of boundary layers 11a and 11b that are stacked. The acoustic velocity of the lateral wave propagating through the boundary layers 11a and 11b is greater than the acoustic velocity of the lateral wave propagating through the temperature compensation film 12, and is less than the acoustic velocity of the lateral wave propagating through the support substrate 10. The thickness T1 of the boundary layer 11 is the sum of the thicknesses T1a and T1b of the boundary layers 11a and 11b. Other structures are the same as those of the first variation of the first embodiment, and the description thereof is thus omitted. As in the second variation of the first embodiment, the boundary layer 11 may include a plurality of the boundary layers 11a and 11b that are made of different materials and are stacked.

### Third Variation of the First Embodiment

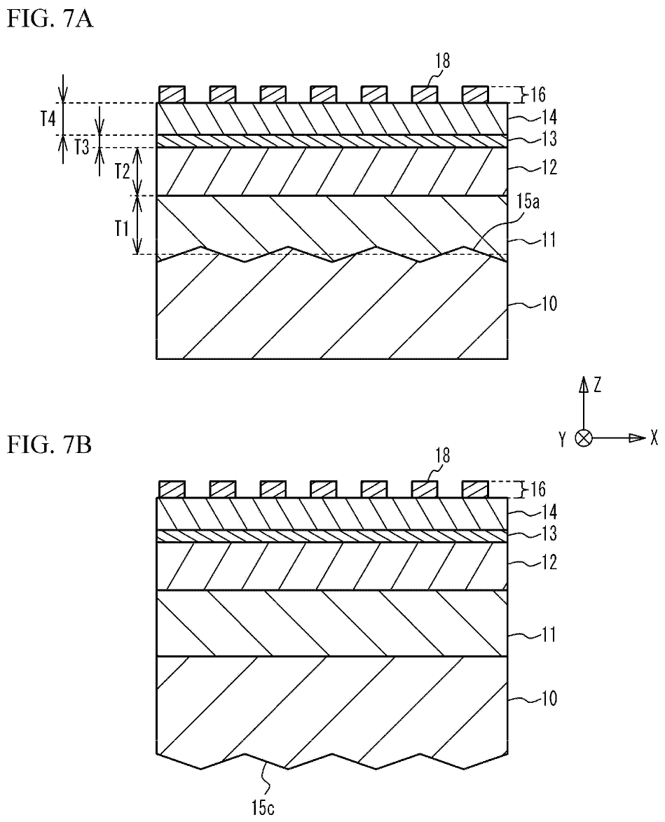

FIG. 7A is a cross-sectional view of an acoustic wave resonator in accordance with a third variation of the first embodiment. As illustrated in FIG. 7A, a boundary face 15a between the support substrate 10 and the boundary layer 11 is a regularly protruding and recessed face. The arithmetic mean roughness Ra of the boundary face 15a is, for example, 0.02 μm or greater. Other boundary faces are flat. The unnecessary wave is scattered by the boundary face 15a, and the spurious response is thereby further reduced. In this case, the thickness T1 of the boundary layer 11 is the average thickness of the boundary layer 11. Other structures are the same as those of the first variation of the first embodiment, and the description thereof is thus omitted.

### Fourth Variation of the First Embodiment

FIG. 7B is a cross-sectional view of an acoustic wave resonator in accordance with a fourth variation of the first embodiment. As illustrated in FIG. 7B, a lower surface 15c of the support substrate 10 is a regularly protruding and recessed surface. The arithmetic mean roughness Ra of the lower surface 15c is, for example, 0.02 μm or greater. Other boundary faces are flat. Other structures are the same as those of the first variation of the first embodiment, and the description thereof is thus omitted.

### Fifth Variation of the First Embodiment

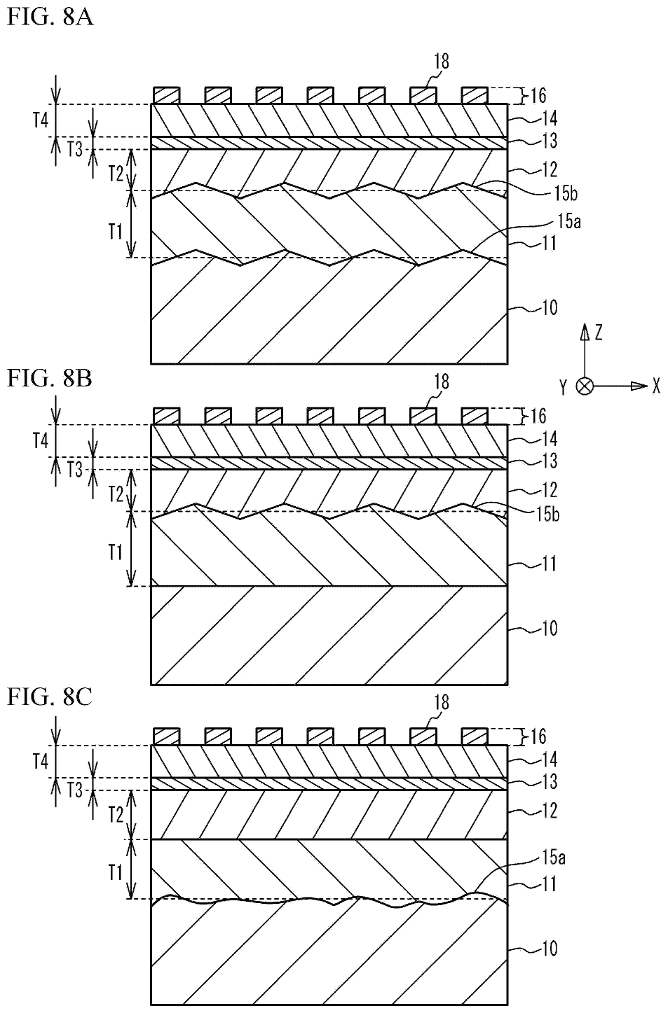

FIG. 8A is a cross-sectional view of an acoustic wave resonator in accordance with a fifth variation of the first embodiment. As illustrated in FIG. 8A, the boundary face 15a between the support substrate 10 and the boundary layer 11 and a boundary face 15b between the boundary layer 11 and the temperature compensation film 12 are regularly protruding and recessed faces. The protrusion and the recess of the boundary face 15b are formed along, for example, the protrusion and the recess of the boundary face 15a. The arithmetic mean roughness Ra of each of the boundary faces 15a and 15b is, for example, 0.02 μm or greater. Other boundary faces are flat. Since the unnecessary wave is diffusely reflected by the boundary faces 15a and 15b, the spurious response is further reduced. In this case, the thickness T1 of the boundary layer 11 is the average thickness of the boundary layer 11, and the thickness T2 of the temperature compensation film 12 is the average thickness of the temperature compensation film 12. Other structures are the same as those of the first variation of the first embodiment, and the description thereof is thus omitted.

### Sixth Variation of the First Embodiment

FIG. 8B is a cross-sectional view of an acoustic wave resonator in accordance with a sixth variation of the first embodiment. As illustrated in FIG. 8B, the boundary face 15b between the boundary layer 11 and the temperature compensation film 12 is a regularly protruding and recessed face. The arithmetic mean roughness Ra of the boundary face 15b is, for example, 0.02 μm or greater. Other boundary faces are flat. Since the unnecessary wave is scattered by the boundary face 15b, the spurious response is further reduced. In this case, the thickness T2 of the temperature compensation film 12 is the average thickness of the temperature compensation film 12. Other structures are the same as those of the first variation of the first embodiment, and the description thereof is thus omitted.

### Seventh Variation of the First Embodiment

FIG. 8C is a cross-sectional view of an acoustic wave resonator in accordance with a seventh variation of the first embodiment. As illustrated in FIG. 8C, the boundary face 15a between the support substrate 10 and the boundary layer 11 is an irregular (i.e., random) rough face. The arithmetic mean roughness Ra of the boundary face 15a is, for example, 0.02 μm or greater. Other boundary faces are flat. Other structures are the same as those of the first variation of the first embodiment, and the description thereof is thus omitted. In the fourth to sixth variations of the first embodiment, instead of the regularly protruding and recessed face, an irregular rough face may be employed.

As in the third to sixth variations of the first embodiment, at least one of faces including the boundary faces between the layers and the lower surface of the support substrate 10 may be a regularly protruding and recessed face. As in the seventh variation of the first embodiment, at least one of faces including the boundary faces between the layers and the lower surface of the support substrate 10 may be an irregular rough face. In the third to seventh variations of the first embodiment, the unnecessary wave is scattered by the protruding and recessed face or the rough face. Therefore, the spurious response is reduced. When the boundary faces between the layers are not flat, the thickness of each layer is the average thickness of each layer. A regularly protruding and recessed face or an irregular rough face may be provided in the first embodiment.

In the first embodiment and the variations thereof, when the acoustic wave that a pair of the comb-shaped electrodes 20 mainly excites is a shear horizontal (SH) wave, a bulk wave is likely to be excited as the unnecessary wave. When the piezoelectric layer 14 is a 36° or greater and 48° or less rotated Y-cut lithium tantalate layer, the SH wave is excited. Therefore, it is preferable to provide the boundary layer 11 in this case. The acoustic wave that a pair of the comb-shaped electrodes 20 mainly excites is not limited to the SH wave, and may be, for example, a Lamb wave.

### Second Embodiment

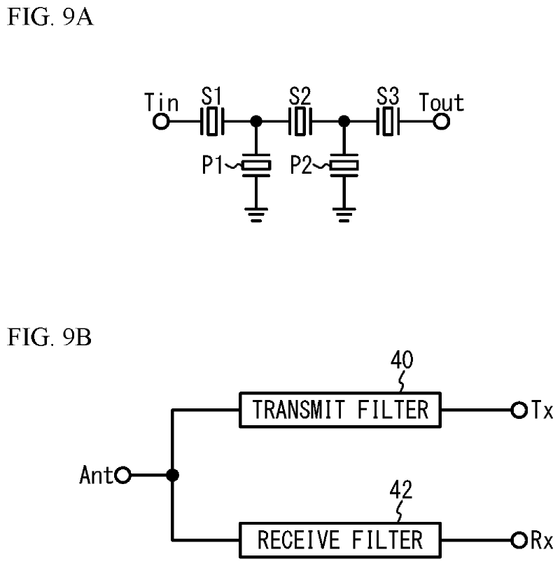

FIG. 9A is a circuit diagram of a filter in accordance with a second embodiment. As illustrated in FIG. 9A, one or more series resonators S1 to S3 are connected in series between an input terminal Tin and an output terminal Tout. One or more parallel resonators P1 and P2 are connected in parallel between the input terminal Tin and the output terminal Tout. The acoustic wave resonator of the first embodiment may be used for at least one resonator selected from a group consisting of the one or more series resonators S1 to S3 and one or more parallel resonators P1 and P2. The number of resonators included in the ladder-type filter can be freely selected. The filter may be a multimode type filter.

### First Variation of the Second Embodiment

FIG. 9B is a circuit diagram of a duplexer in accordance with a first variation of the second embodiment. As illustrated in FIG. 9B, a transmit filter 40 is connected between a common terminal Ant and a transmit terminal Tx. A receive filter 42 is connected between the common terminal Ant and a receive terminal Rx. The transmit filter 40 transmits signals in the transmit band as transmission signals to the common terminal Ant among high-frequency signals input from the transmit terminal Tx, and suppresses signals with other frequencies. The receive filter 42 transmits signals in the receive band as reception signals to the receive terminal Rx among high-frequency signals input from the common terminal Ant, and suppresses signals with other frequencies. At least one of the transmit filter 40 or the receive filter 42 may be the filter of the second embodiment.

A duplexer has been described as an example of the multiplexer, but the multiplexer may be a triplexer or a quadplexer.

Although the embodiments of the present invention have been described in detail, the present invention is not limited to such a specific embodiment, and it is to be understood that the various change, substitutions, and alterations could be made hereto without departing from the spirit and scope of the invention.

What is claimed is:

1. An acoustic wave device comprising:
a support substrate;
a piezoelectric layer located over the support substrate;
at least one pair of comb-shaped electrodes disposed on the piezoelectric layer, each of the at least one pair of comb-shaped electrodes including electrode fingers that excite an acoustic wave;
a temperature compensation film interposed between the support substrate and the piezoelectric layer, the temperature compensation film having a thickness equal to or less than 2 times an average pitch of the electrode fingers, a temperature coefficient of elastic constant of the temperature compensation film being opposite in sign to a temperature coefficient of elastic constant of the piezoelectric layer; and
a boundary layer interposed between the support substrate and the temperature compensation film, the boundary layer having a thickness equal to or greater than 2.2 times the average pitch of the electrode fingers, an acoustic velocity of a lateral wave propagating through the boundary layer being less than an acoustic velocity of a lateral wave propagating through the support substrate and greater than an acoustic velocity of a lateral wave propagating through the temperature compensation film.

2. The acoustic wave device according to claim 1, wherein the acoustic velocity of the lateral wave propagating through the temperature compensation film is less than the acoustic velocity of the lateral wave propagating through the piezoelectric layer.

3. The acoustic wave device according to claim 1, wherein a distance between a first surface, which is located closer to the support substrate, of the temperature compensation film and a second surface, which is located closer to the pair of comb-shaped electrodes, of the piezoelectric layer is equal to or less than two times the average pitch of the electrode fingers.

4. The acoustic wave device according to claim 1, wherein a thickness of the boundary layer is equal to or greater than 4.0 times the average pitch of the electrode fingers.

5. The acoustic wave device according to claim 1, wherein the acoustic velocity of the lateral wave propagating through the support substrate is equal to or greater than 1.1 times the acoustic velocity of the lateral wave propagating through the boundary layer.

6. The acoustic wave device according to claim 1, wherein the acoustic velocity of the lateral wave propagating through the boundary layer is equal to or greater than 1.1 times the acoustic velocity of the lateral wave propagating through the temperature compensation film.

7. The acoustic wave device according to claim 1, wherein the lateral wave is a bulk wave.

8. The acoustic wave device according to claim 3, further comprising a bonding layer interposed between the temperature compensation film and the piezoelectric layer.

9. The acoustic wave device according to claim 1, wherein the piezoelectric layer is a single crystal mainly composed of lithium tantalate or lithium niobate, the temperature compensation film is a polycrystal mainly composed of silicon oxide or an amorphia mainly composed of silicon oxide, the boundary layer is a polycrystal mainly composed of aluminum oxide or an amorphia mainly composed of aluminum oxide, and the support substrate is a sapphire substrate or a silicon carbide substrate.

10. The acoustic wave device according to claim 1, wherein the average pitch of the electrode fingers is a value calculated by dividing a length of the at least one pair of comb-shaped electrodes in a direction in which the electrode fingers are arranged by the number of the electrode fingers.

11. A filter comprising:
the acoustic wave device according to claim 1.

12. A multiplexer comprising:
the filter according to claim 11.
